(19) United States
(12) Patent Application Publication
(10) Pub. No.: US 2008/0087930 A1
(43) Pub. Date: Apr. 17, 2008

(54) Capicitor Using Binary Metal Electrode, Semiconductor Device Having The Capacitor And Method of Fabricating The Same

(76) Inventors: Jong-Cheol Lee, Seoul (KR); Ki-Vin Im, Seongnam-si (KR); Hoon-Sang Choi, Seoul (KR); Eun-Ae Chung, Suwon-si (KR); Sang-Yeol Kang, Seoul (KR)

Correspondence Address: Frank Chau, Esq.;F. CHAU & ASSOCIATES, LLC, 130 Woodbury Road, Woodbury, NY, 11797, US

(21) Appl. No.: 11/733,943

(22) Filed: Apr. 11, 2007

(30) Foreign Application Priority Data
Oct. 11, 2006 (KR) 2006-00989959

(51) Int. Cl. H01L 27/108; H01G 4/008; H01L 21/20

(52) U.S. Cl. 257/300; 361/305; 438/240; 257/E27.084; 257/E21.09

(57) ABSTRACT

A capacitor includes a first electrode having a conductive pattern and an anti-oxidation pattern contacting the conductive pattern and a second electrode overlapping the first electrode. The capacitor further includes a capacitor dielectric layer disposed between the first and second electrodes, and having a blanket dielectric layer and a partial dielectric layer. The blanket dielectric layer is disposed between the first and second electrodes, and the partial dielectric layer is disposed between the blanket dielectric layer and the anti-oxidation pattern.

### CROSS-REFERENCE TO RELATED APPLICATION

This application claims the benefit of Korean Patent Application No. 2006-0098959, filed Oct. 11, 2006, the disclosure of which is hereby incorporated by reference herein in its entirety.

### BACKGROUND OF THE INVENTION

1. Technical Field

The present disclosure relates to a semiconductor device and to a method of fabricating the same, and more particularly, to a capacitor using a binary metal electrode, a semiconductor device having the capacitor, and to a method of fabricating the same.

2. Description of the Related Art

Semiconductor devices such as a dynamic random access memory (DRAM) typically include discrete devices such as a capacitor and a transistor. To highly integrate the semiconductor devices, the technology of geometrically arranging these discrete devices has been researched. Also, relatively high capacitance and low leakage current are generally required to highly integrate the capacitor.

For example, a capacitor comprises a lower electrode and an upper electrode which overlap each other, and a capacitor dielectric layer is disposed between the upper and lower electrodes. The capacitance of the capacitor is proportional to the overlap area between the upper and lower electrodes, and inversely proportional to the electrical resistance of the upper and lower electrodes and an equivalent oxide thickness of the capacitor dielectric layer. Accordingly, a cylindrical metal-insulator-metal (MIM) capacitor has been proposed.

The cylindrical MIM capacitor typically employs a lower electrode having a cylindrical structure to relatively increase the overlap area between the upper and lower electrodes. The upper and lower electrodes are formed of a metal layer to reduce the electrical resistance thereof. For example, a technique of forming the lower electrode using a titanium nitride (TiN) layer is applied to the MIM capacitor. It has been reported that the lower electrode formed of a TiN layer has improved electrical reliability as it has low resistivity and suppresses generation of parasitic capacitance due to a depletion layer.

A conventional method of manufacturing the cylindrical MIM capacitor using a TiN layer may include forming a cylindrical lower electrode using a TiN layer; forming a capacitor dielectric layer on the cylindrical lower electrode, and forming an upper electrode on the capacitor dielectric layer.

The process of forming the capacitor dielectric layer uses an oxidant such as oxygen (O₂) or ozone (O₃). The oxidant reacts with the TiN layer to form a parasitic oxide layer such as a titanium oxynitride (TiON) layer at an interface between the lower electrode and the capacitor dielectric layer. The parasitic oxide layer, e.g., the TiON layer, has conductivity.

Moreover, as the oxidant is not provided sufficiently into the cylindrical lower electrode, the capacitor dielectric layer formed in the cylindrical lower electrode is relatively thin and ununiform. As a result, the conductive parasitic oxide layer and the thin and ununiform capacitor dielectric layer may cause an increase in leakage current of the cylindrical MIM capacitor and the deterioration of the reliability of the device.

Another method of manufacturing the MIM capacitor is described in U.S. Pat. No. 6,881,642 B2 entitled “Method of Forming a MIM Capacitor with Metal Nitride Electrode” by Basceri et al.

There is a need in the art for a capacitor having a high capacitance and a significantly low leakage current characteristic compared to the conventional art and a semiconductor device which includes this capacitor.

### SUMMARY OF THE INVENTION

An exemplary embodiment of the invention provides a capacitor capable of obtaining high capacitance and low leakage current characteristics.

Another exemplary embodiment of the invention provides a semiconductor device including a capacitor capable of obtaining high capacitance and low leakage current characteristics.

Still another exemplary embodiment of the invention provides a method of fabricating the semiconductor device which includes a capacitor capable of obtaining high capacitance and low leakage current characteristics.

In accordance with an exemplary embodiment of the present invention a capacitor is provided. The capacitor includes a first electrode and a second electrode overlapping the first electrode. The first electrode has a conductive pattern and an anti-oxidation pattern contacting the conductive pattern. A capacitor dielectric layer is disposed between the first and second electrodes. The capacitor dielectric layer has blanket and partial dielectric layers. The blanket dielectric layer is disposed between the first and second electrodes. The partial dielectric layer is disposed between the blanket dielectric layer and the anti-oxidation pattern.

In some exemplary embodiments of the present invention, the conductive pattern may be formed of a titanium nitride (TiN) layer. Also, the conductive pattern may have a cylindrical or concave structure. Here the anti-oxidation pattern may cover an inner wall of the conductive pattern. Further, the blanket dielectric layer may cover inner and outer walls of the first electrode.

In other exemplary embodiments, the anti-oxidation pattern may be formed of a binary metal electrode containing aluminum (Al). Here, the anti-oxidation pattern may be formed of a titanium aluminum nitride (TiAlN) layer. The partial dielectric layer may be an aluminum oxide (AlO) layer.

In still other exemplary embodiments, the blanket dielectric layer may include a material layer having a permittivity higher than or equal to that of the AlO layer. The blanket dielectric layer may include one selected from the high-k dielectric group consisting of a hafnium oxide (HfO) layer, a zirconium oxide (ZrO) layer, an AlO layer, a titanium oxide (TiO) layer, and a combination thereof.

In yet other exemplary embodiments, the second electrode may comprise a TiN layer or a TiAlN layer.

In accordance with an exemplary embodiment of the present invention, a semiconductor device is provided. The device includes a first electrode and a second electrode overlapping the first electrode. The first electrode has a conductive pattern and an anti-oxidation pattern contacting the conductive pattern. A capacitor dielectric layer is disposed between the first and second electrodes. The capacitor dielectric layer has a blanket dielectric layer and a partial dielectric layer. The blanket dielectric layer is disposed between the first and second electrodes. The partial dielectric layer is disposed between the blanket dielectric layer and the anti-oxidation pattern. Source and drain regions of a transistor electrically connected with the first electrode are also provided.

In some exemplary embodiments of the present invention, the anti-oxidation pattern may be formed of a binary metal electrode containing aluminum. In this case, the anti-oxidation pattern may be formed of a TiAlN layer. The partial dielectric layer may be an AlO layer. In other exemplary embodiments, an interlayer insulating layer may be disposed between the first electrode and the source and drain regions. A contact plug passing through the interlayer insulating layer between the first electrode and the source and drain regions may be disposed. An ohmic contact layer may be disposed between the conductive pattern and the contact plug. The ohmic contact layer may be a titanium silicide (TiSi) layer.

In accordance with another exemplary embodiment of the present invention, a method of fabricating a semiconductor device is provided. The method includes forming a first electrode on a substrate. The first electrode has a conductive pattern and an anti-oxidation pattern contacting the conductive pattern. A capacitor dielectric layer covering the first electrode is formed. The capacitor dielectric layer has a blanket dielectric layer covering the first electrode and a partial dielectric layer between the blanket dielectric layer and the anti-oxidation pattern. A second electrode overlapping the first electrode is also formed.

In some exemplary embodiments of the present invention the conductive pattern may be formed in a cylindrical or concave structure. The anti-oxidation pattern may be formed to cover an inner wall of the conductive pattern.

In other exemplary embodiments, the anti-oxidation pattern may be formed of a binary metal electrode containing aluminum. The anti-oxidation pattern may be formed of a TiAlN layer.

In still other exemplary embodiments, the partial dielectric layer having an AlO layer may be formed by oxidizing the surface of the anti-oxidation pattern. The partial dielectric layer may be formed by making O₂ or O₃ flow on a surface of the anti-oxidation pattern, or by a rapid thermal oxidation method. The blanket dielectric layer may be formed on the partial dielectric layer and the conductive pattern.

In yet other exemplary embodiments, after forming the blanket dielectric layer on the anti-oxidation pattern and the conductive pattern, the partial dielectric layer having an AlO layer may be formed by oxidizing the surface of the anti-oxidation pattern.

In yet other exemplary embodiments, source and drain regions of a transistor electrically connected to the first electrode may be formed on the substrate. An interlayer insulating layer may be formed between the source and drain regions and the first electrode. A contact plug may be formed to pass through the interlayer insulating layer and contact the source and drain regions and the first electrode. An ohmic contact layer may be formed between the conductive pattern and the contact plug

### BRIEF DESCRIPTION OF THE DRAWINGS

Exemplary embodiments of the invention can be understood in more detail from the following description taken in conjunction with the accompanying drawings, in which:

FIG. 1 is cross-sectional view of a semiconductor device having a capacitor using a binary metal electrode according to an exemplary embodiment of the present invention.

FIGS. 2 to 7 are cross-sectional views illustrating a method of fabricating a semiconductor device having a capacitor using a binary metal electrode according to an exemplary embodiment of the present invention.

### DETAILED DESCRIPTION OF THE EXEMPLARY EMBODIMENTS OF THE INVENTION

The present invention will now be described more fully hereinafter with reference to the accompanying drawings, in which exemplary embodiments of the invention are shown. This invention may, however, be embodied in different forms and should not be construed as limited to the exemplary embodiments set forth herein. In the drawings the thickness of layers and regions are exaggerated for clarity. In addition when a layer is described to be formed on other layer or on a substrate, which means that the layer may be formed on the other layer or on the substrate, or a third layer may be interposed between the layer and the other layer or the substrate. Like reference numerals denote like elements throughout the specification.

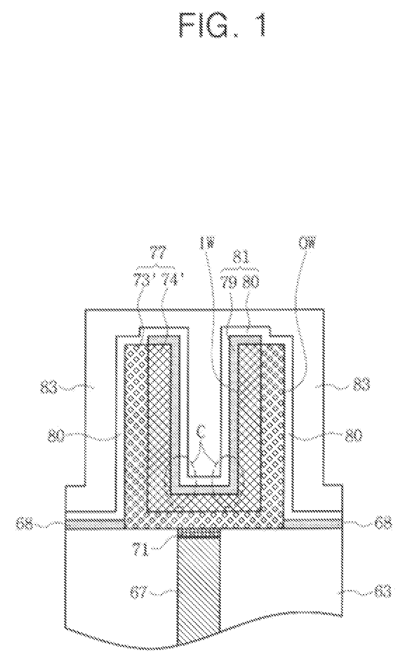

First, a semiconductor device having a capacitor using a binary metal electrode according to an exemplary embodiment of the present invention will be described with reference to FIG. 1.

Referring to FIG. 1, the semiconductor device may include a first electrode 77 disposed on an interlayer insulating layer 63 and a second electrode 83 overlapping the first electrode 77.

The interlayer insulating layer 63 may be, for example a silicon oxide (SiO) layer. The interlayer insulating layer 63 may be covered with an etch stop layer 68. The etch stop layer 68 may be, for example, a silicon nitride (SiN) layer or a silicon oxynitride (SiON) layer. A buried contact plug 67 passing through the interlayer insulating layer 63 may be disposed in the interlayer insulating layer 63. The first electrode 77 may be in contact with the buried contact plug 67. The buried contact plug 67 may be formed of, for example a poly silicon layer.

For example, titanium silicide layer 71 may be provided between the buried contact plug 67 and the first electrode 77. The titanium silicide layer 71 may cover a top surface of the buried contact plug 67. The titanium silicide layer 71 may function as an ohmic contact layer improving contact resistance between the buried contact plug 67 and the first electrode 77. In another embodiment of the present invention the titanium silicide layer 71 may be another metal silicide layer.

The first electrode 77 may include a conductive pattern 73′ and an anti-oxidation pattern 74′ contacting the conductive pattern 73′. The first electrode 77 may act as a storage node of a DRAM.

The conductive pattern 73′ may have a cylindrical or concave structure. The conductive pattern 73′ may be formed of a metal nitride layer for example, a titanium nitride (TiN) layer. The TiN layer has high mechanical strength and improved electrical conductivity. That is, although the conductive pattern 73, is fabricated in a cylindrical structure having a high aspect ratio, it may endure physical damage or modification. The conductive pattern 73′ may contact the titanium silicide layer 71. Thus, the conductive pattern 73, may be electrically connected with the buried contact plug 67.

The anti-oxidation pattern 74, may cover an inner wall of the conductive pattern 73′. The anti-oxidation pattern 74′ may be a binary metal electrode containing, for example, aluminum (Al). Here, the anti-oxidation pattern 74′ may be formed of, for example, a titanium aluminum nitride (TiAlN) layer. The TiAlN layer has higher thermal stability and oxidation resistance than the TiN layer. That is, the TiAlN layer may function to prevent formation of a conductive parasitic oxide layer such as titanium oxynitride (TiON) layer in the first electrode 77.

As described above, the first electrode 77 may have a cylindrical or concave structure. An inner wall IW of the first electrode 77 may be a surface of the anti-oxidation pattern 74′, and an outer wall OW of the first electrode 77 may be a surface of the conductive pattern 73′.

The second electrode 83 may be formed of a conductive layer such as, for example, a TiN or TiAlN layer. The second electrode 83 may cover the inner wall IW and the outer wall OW of the first electrode 77.

A capacitor dielectric layer 81 may be interposed between the first electrode 77 and the second electrode 83. The capacitor dielectric layer 81 may include a blanket dielectric layer 80 and a partial dielectric layer 79.

The blanket dielectric layer 80 may be disposed between the first and second electrodes 77 and 83. The blanket dielectric layer 80 may cover the inner wall IW and the outer wall OW of the first electrode 77. Also, the etch stop layer 68 may be covered with the blanket dielectric layer 80, which may be a material layer having a permittivity higher than or equal to that of an aluminum oxide (AlO) layer. The blanket dielectric layer 80 may be, for example, one selected from the high-k dielectric group consisting of a hafnium oxide (HfO) layer, a zirconium oxide (ZrO) layer; an aluminum oxide (AlO) layer, a titanium oxide (TiO) layer, and a combination thereof.

The partial dielectric layer 79 may be disposed between the blanket dielectric layer 80 and the anti-oxidation pattern 74′. That is, the partial dielectric layer 79 may cover the surface of the anti-oxidation pattern 74′. The partial dielectric layer 79 may be an insulating layer formed by oxidation of aluminum contained in the anti-oxidation pattern 74′. The partial dielectric layer 79 may be a very thin film having a thickness of about 0.1 to about 1 nanometer (nm). However, the partial dielectric layer 79 may densely cover a lower corner region C inside the first electrode 77. The partial dielectric layer 79 may be, for example an aluminum oxide (AlO) layer. The aluminum oxide (AlO) layer has a higher permittivity than a silicon oxide (SiO) layer.

The first electrode 77, the capacitor dielectric layer 81 and the second electrode 83 may constitute a capacitor. The first electrode 77 may function as a lower electrode of the capacitor, and the second electrode 83 may function as an upper electrode of the capacitor.

One end of the buried contact plug 67 may be connected with source and drain regions of a transistor. That is, the first electrode 77 may be electrically connected with the source and drain regions of the transistor through the titanium silicide layer 71 and the buried contact plug 67.

As described above, the first electrode 77 may include the cylindrical conductive pattern 73′ and the anti-oxidation pattern 74′ covering the inner wall of the cylindrical conductive pattern 73′. The surface of the anti-oxidation pattern 74′ may be covered with the partial dielectric layer 79. The partial dielectric layer 79 may be, for example, an aluminum oxide (AlO) layer formed by oxidation of aluminum contained in the anti-oxidation pattern 74′. Accordingly, the partial dielectric layer 79 may densely cover the lower corner regions C inside the first electrode 77. That is, although the first electrode 77 has a cylindrical structure with a high aspect ratio, the partial dielectric layer 79 may densely cover the lower corner regions C inside the first electrode 77. The partial dielectric layer 79 and the blanket dielectric layer 80 may constitute the capacitor dielectric layer 81.

As a result, according to the exemplary embodiments of the present invention, a semiconductor device having a capacitor having high capacitance and low leakage current in comparison with conventional art may be realized.

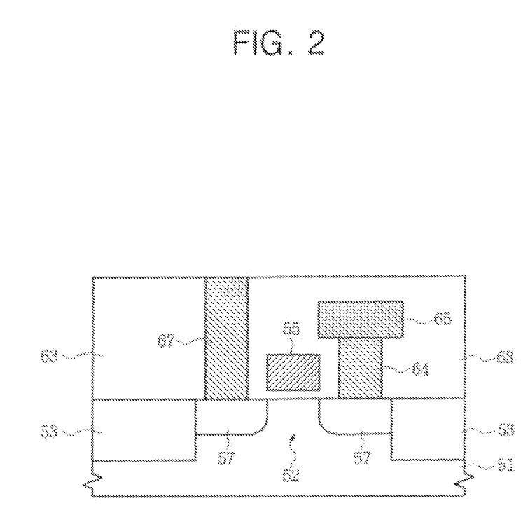

A method of fabricating a semiconductor device having a capacitor using a binary metal electrode according to an exemplary embodiment of the present invention will now be described with reference to FIGS. 2 to 7.

Referring to FIG. 2, an isolation layer 53 may be formed in a substrate 51. The substrate 51 may be a semiconductor substrate, for example, a silicon wafer or a silicon-on-insulator (SOI) wafer. The isolation layer 53 may be formed by, for example, a common shallow trench isolation (STI) process. The isolation layer 53 may be, for example, an insulating layer such as a high-density plasma (HDP) oxide layer. An active region 52 may be defined by the isolation layer 53.

A gate electrode 55 may be formed on and insulated from the substrate 51 having the isolation layer 53. The gate electrode 55 may be formed of, for example, a polysilicon layer, a metal silicide layer, or a stacked layer thereof.

Impurity ions may be implanted into the active region 52 using the gate electrode 55 as an ion implantation mask to form source and drain regions 57. The source and drain regions 57 may be implanted with impurity ions having a different conductivity than the active region 52. For example, p-type impurity ions may be implanted into the active region 52. In this case, high concentration n-type impurity ions may be implanted into the source and drain regions 57. The source and drain regions 57, the active region 52 and the gate electrode 55 may constitute a MOS transistor.

An interlayer insulating layer 63 may be formed on the substrate 51 having the source and drain regions 57. The interlayer insulating layer 63 may be, for example a silicon oxide (SiO) layer. A bit plug 64 and a bit line 65 may be formed in the interlayer insulating layer 63. The bit line 65 and the bit plug 64 may be formed of a conductive material layer such as, for example, a polysilicon layer or a tungsten layer. The bit line 65 may be electrically connected to one of the source and drain regions 57 through the bit plug 64.

The interlayer insulating layer 63 may be patterned to form a contact hole exposing the other of the source and drain regions 57, A conductive layer may be formed on the interlayer insulating layer 63 to fill the contact hole. The conductive layer is planarized by a chemical mechanical polishing (CMP) process to expose the top surface of the interlayer insulating layer 63. Thus, a buried contact plug 67 may be formed in the contact hole. The buried contact plug 67 may be formed of, for example, a polysilicon layer.

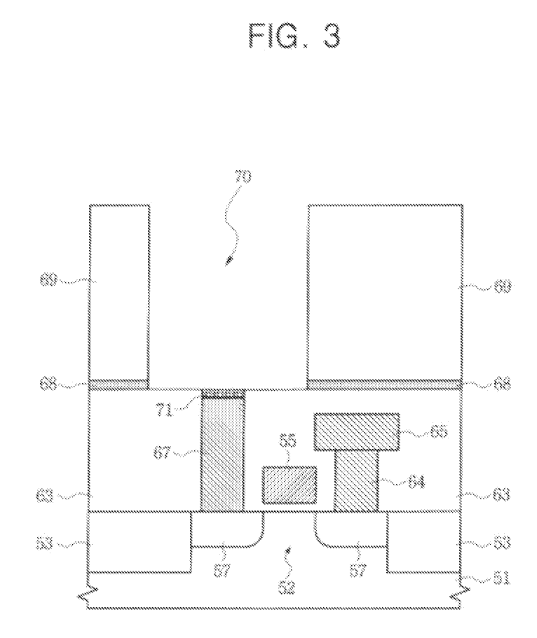

Referring to FIG. 3, an etch stop layer 68 may be formed on the buried contact plug 67 and the interlayer insulating layer 63. The etch stop layer 68 may be, for example, a silicon oxynitride (SiON) layer or a silicon nitride (SiN) layer.

A molding layer 69 may be formed on the etch stop layer 68. The molding layer 69 may be formed of a material layer having an etch selectivity with respect to the etch stop layer 68. For example, the molding layer 69 may be a silicon oxide layer such as a plasma enhanced tetraethylorthosilicate (PE-TEOS) oxide layer, a borophosphosilicate glass (BPSG) layer, or a phosphosilicate glass (PSG) layer.

A storage node hole 70 exposing the buried contact plug 67 may be formed by patterning the molding layer 69 and the etch stop layer 68.

For example, a titanium layer may be formed on the substrate 51 having the storage node hole 70. The titanium layer may be deposited by, for example, chemical vapor deposition (CVD). During the formation of the titanium layer, a titanium silicide layer 71 may be formed on the surface of the buried contact plug 67. The titanium silicide layer 71 may be formed by interaction between the titanium layer and the buried contact plug 67.

The titanium silicide layer 71 may function as an ohmic contact layer improving contact resistance between the buried contact plug 67 and a first electrode to be formed in a subsequent process. The titanium silicide layer 71 may be formed by a thermal treatment process performed in an atmosphere of ammonia (NH₃) plasma after forming the titanium layer. Then, the titanium layer which does not react with the buried contact plug 67 may be removed to expose the titanium silicide layer 71. However, the process of exposing the titanium silicide layer 71 may be omitted.

Also, the titanium silicide layer 71 may be another metal silicide layer.

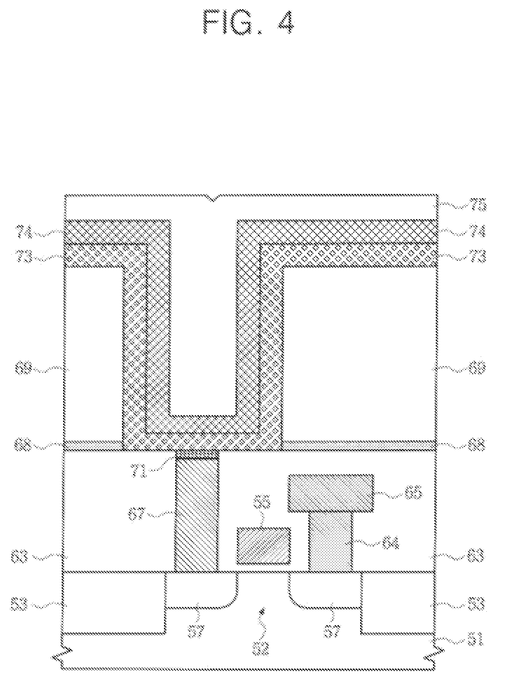

Referring to FIG. 4, a conductive layer 73 may be formed on the substrate 51 having the titanium silicide layer 71. The conductive layer 73 may be a metal nitride layer such as, for example, a TiN layer. The TiN layer has high mechanical strength and excellent electrical conductivity. The conductive layer 73 may contact the titanium silicide layer 71. Thus, the conductive layer 73 may be electrically connected to the buried contact plug 67.

An anti-oxidation layer 74 may be formed on the conductive layer 73. The anti-oxidation layer 74 may be a binary metal layer containing aluminum (Al). For example, the anti-oxidation layer 74 may be a TiAlN layer. The TiAlN layer has a higher thermal stability and oxidation resistance than the TiN layer.

The conductive layer 73 and the anti-oxidation layer 74 may be formed by, for example, a CVD method, a combination of CVD and nitriding, or an atomic layer deposition (ALD) method.

The conductive layer 73 and the anti-oxidation layer 74 may be formed to uniformly cover the inside of the storage node hole 70. A sacrificial layer 75 may be formed on the substrate 51 having the anti-oxidation layer 74 to fill the storage node hole 70. The sacrificial layer 75 may be the same material layer as the molding layer 69.

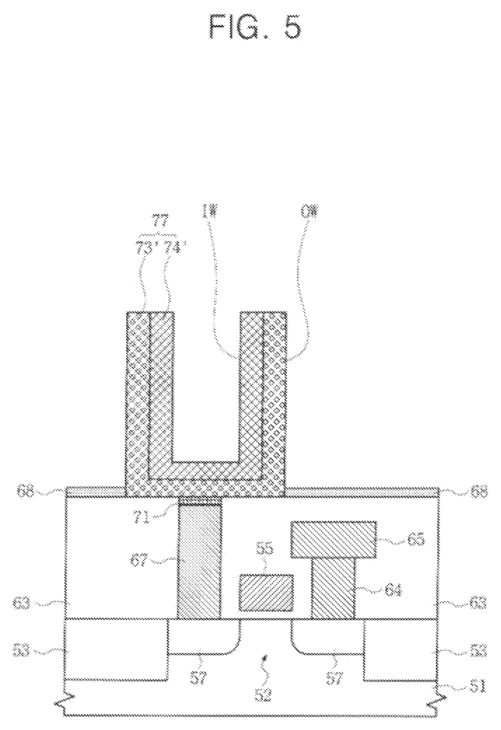

Referring to FIG. 5, the sacrificial layer 75, the anti-oxidation layer 74 and the conductive layer 73 may be planarized so as to expose the molding layer 69. The planarization may be performed by, for example, CMP or etch back. As a result, a conductive pattern 73′ and an anti-oxidation pattern 74′ may be formed.

The conductive pattern 73′ and the anti-oxidation pattern 74′ may constitute a first electrode 77. Here the conductive pattern 73′ may be formed to have a cylindrical structure. The anti-oxidation pattern 74′ may be formed to cover the inside of the cylindrical conductive pattern 73′. The first electrode 77 may function as a storage node of a DRAM.

In another exemplary embodiment of the present invention, the conductive pattern 73′ may be formed to have a concave structure. Here, the anti-oxidation pattern 74; may be formed to cover the inner surface of the concave conductive pattern 73′.

Then, the molding layer 69 and the sacrificial layer 75 may be removed to expose the first electrode 77. The removal of the molding layer 69 and the sacrificial layer 75 may be performed by a wet cleaning process or an isotropic dry etching process. As a result, the first electrode 77 may be formed to have a cylindrical or concave structure. The anti-oxidation pattern 74′ may be exposed at an inner wall IW of the first electrode 77 and the conductive pattern 73′ may be exposed at an outer wall OW of the first electrode 77.

The structure and size of the first electrode 77 may be determined by the thickness of the molding layer 69 and the diameter of the storage node hole 70. For example, if the molding layer 69 is formed thick, the first electrode 77 may be formed to have a high aspect ratio.

The conductive pattern 73; may be formed of a metal nitride layer such as, for example, a TiN layer. The TiN layer may have high mechanical strength and improved electrical conductivity. That is, the conductive pattern 73′ may endure physical damage or modification even if it has a cylindrical structure having a high aspect ratio.

The anti-oxidation pattern 74, may be formed of a binary metal containing Al such as the TiAlN layer. The TiAlN layer has a higher thermal stability and oxidation resistance than the TiN layer. Thus, a conductive parasitic oxide layer such as, for example, a titanium oxynitride (TiON) layer may be suppressed from being formed on the inner wall IW of the first electrode 77.

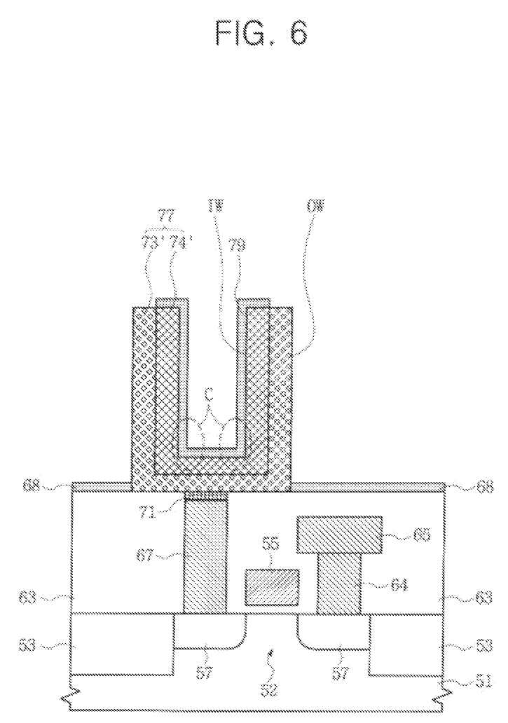

Referring to FIG. 6, a partial dielectric layer 79 may be formed by oxidizing the exposed surface of the anti-oxidation pattern 74′. The partial dielectric layer 79 may be formed, for example, by making oxygen (O₂) or ozone (O) flow on the exposed surface of the anti-oxidation pattern 74′, or by a rapid thermal oxidation method.

For example, when the anti-oxidation pattern 74′ is the TiAlN layer, the partial dielectric layer 79 may be an aluminum oxide (AlO) layer. Here, the AlO layer may be formed by oxidizing Al contained in the anti-oxidation pattern 74′. Thus, the partial dielectric layer 79 may densely cover the lower corner regions C inside the first electrode 77. Also, the partial dielectric layer 79 may be formed of a thin film having a thickness of about 0.1 to about 1 nm. The AlO layer has improved insulation characteristics and a higher permittivity than a silicon oxide layer.

However, the formation of the partial dielectric layer 79 may be performed after formation of a blanket dielectric layer which will be performed subsequently.

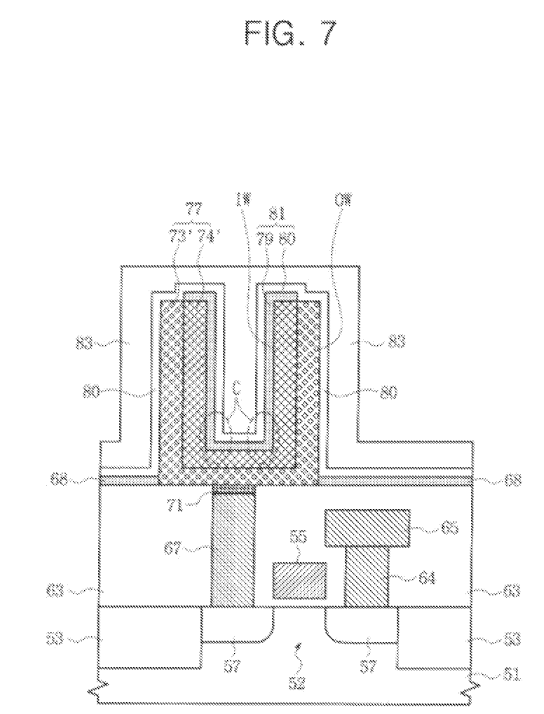

Referring to FIG. 7, a blanket dielectric layer 80 may be formed to cover the first electrode 77 and the etch stop layer 68. The blanket dielectric layer 80 may cover the outer wall OW of the first electrode 77 and the partial dielectric layer 79. The blanket dielectric layer 80 may be a material layer having a permittivity higher than or equal to that of the AlO layer. The blanket dielectric layer 80 may be formed of, for example, one selected from the high-k dielectric group consisting of an hafnium oxide (HfO) layer, a Zirconium (ZrO) layer, an aluminum oxide (AlO) layer, a titanium oxide (TiO) layer and a combination thereof. For example, the blanket dielectric layer 80 may be formed by an atomic layer deposition (ALD) method.

The partial dielectric layer 79 and the blanket dielectric layer 80 may constitute a capacitor dielectric layer 81.

A second electrode 83 may be formed on the substrate 51 having the capacitor dielectric layer 81. The second electrode 83 may overlap the first electrode 77. That is, the second electrode 83 may cover the inner wall IW and the outer wall OW of the first electrode 77. The second electrode 83 may be formed of a metal layer such as, for example, a TiN layer or a TiAlN layer.

In another exemplary embodiment, the partial dielectric layer 79 may be formed after forming the blanket dielectric layer 80. For example, the molding layer 69 and the sacrificial layer 75 may be removed to expose the first electrode 77, and then the blanket dielectric layer 80 may be formed. The partial dielectric layer 79 may be formed at an interface between the blanket dielectric layer 80 and the antioxidation pattern 74′ using, for example, a plasma oxidation method or a rapid thermal oxidation method.

When the conductive pattern 73′ is the TiN layer, a parasitic oxide layer such as, for example, a TiON layer may be formed on the surface of the conductive pattern 73′ while forming the partial dielectric layer 79 and the blanket dielectric layer 80. That is, the parasitic oxide layer may be formed on the outer wall OW of the first electrode 77. However, the TiON layer has conductivity. Also, the blanket dielectric layer 80 may be formed more thickly and uniformly on the outer wall OW of the first electrode 77 than on the inner wail IW of the first electrode 77. On the other hand, the blanket dielectric layer 80 may be formed more thinly and ununiformly on the inner wall IW of the first electrode 77 than on the outer wall OW thereof. However, the inner wall IW of the first electrode 77 may obtain a sufficient equivalent oxide thickness of the capacitor dielectric layer 81 by the partial dielectric layer 79.

The first electrode 77, the capacitor dielectric layer 81 and the second electrode 83 may constitute a capacitor. The conductive pattern 73′ may be electrically connected to the source and drain regions 57 of the transistor through the titanium silicide layer 71 and the buried contact plug 67. That is, the capacitor may be electrically connected to the transistor.

As described above, the first electrode 77 may be formed to have the conductive pattern 73′ and the anti-oxidation pattern 74′. The conductive pattern 73′ may be formed in a cylindrical structure, and the anti-oxidation pattern 74′ may be formed to cover the inside of the cylindrical conductive pattern 73′. The partial dielectric layer 79 formed of an AlO layer is formed, for example, by oxidizing Al contained in the anti-oxidation pattern 74′. Thus, even if the first electrode 77 has a cylindrical structure having a high aspect ratio, the partial dielectric layer 79 may densely cover the lower corner regions C inside the first electrode 77. The AlO layer has a higher permittivity than a silicon oxide layer. As a result, the capacitor may have a significantly lower leakage current characteristic than the conventional capacitor.

According to exemplary embodiments of the present invention, a capacitor dielectric layer disposed between a first electrode and a second electrode overlapping each other is provided. The first electrode may include a cylindrical conductive pattern and an anti-oxidation pattern which covers the inside of the cylindrical conductive pattern. The anti-oxidation pattern may be a binary metal electrode containing aluminum such as, for example, a TiAlN layer. The capacitor dielectric layer has blanket and partial dielectric layers. The partial dielectric layer may be, for example, an AlO layer formed by oxidizing aluminum contained in the anti-oxidation pattern. That is, even if the first electrode has a cylindrical structure having a high aspect ratio, the partial dielectric layer may densely cover lower corner regions inside the first electrode. Thus, a capacitor having a high capacitance and a significantly low leakage current characteristic compared to the conventional art and a semiconductor device comprising the capacitor may be provided.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A capacitor comprising:
a first electrode having a conductive pattern and an anti-oxidation pattern contacting the conductive pattern;
a second electrode overlapping the first electrode; and
a capacitor dielectric layer disposed between the first and second electrodes, and having a blanket dielectric layer and a partial dielectric layer,
wherein the blanket dielectric layer is disposed between the first and second electrodes, and the partial dielectric layer is disposed between the blanket dielectric layer and the anti-oxidation pattern.

2. The capacitor according to claim 1, wherein the conductive pattern is a titanium nitride (TiN) layer.

3. The capacitor according to claim 1, wherein the conductive pattern has one of a cylindrical or concave structure.

4. The capacitor according to claim 3, wherein the anti-oxidation pattern covers an inner wall of the conductive pattern.

5. The capacitor according to claim 4, wherein the blanket dielectric layer covers inner and outer walls of the first electrode.

6. The capacitor according to claim 4, wherein the anti-oxidation pattern is a binary metal electrode containing aluminum.

7. The capacitor according to claim 6, wherein the anti-oxidation pattern is a titanium aluminum nitride (TiAlN) layer.

8. The capacitor according to claim 6, wherein the partial dielectric layer is an aluminum oxide (AlO) layer.

9. The capacitor according to claim 8, wherein the blanket dielectric layer comprises a material layer having a permittivity higher than or equal to that of the AlO layer.

10. The capacitor according to claim 9, wherein the blanket dielectric layer comprises one selected from the high-k dielectric group consisting of a hafnium oxide (HfO) layer, a zirconium oxide (ZrO) layer, an aluminum oxide (AlO) layer, a titanium oxide (TiO) layer and a combination thereof.

11. The capacitor according to claim 1, wherein the second electrode comprises one of a titanium nitride (TiN) layer or a titanium aluminum nitride (TiAlN) layer.

12. A semiconductor device comprising
a first electrode having a conductive pattern and an anti-oxidation pattern contacting the conductive pattern;
a second electrode overlapping the first electrode.
a capacitor dielectric layer disposed between the first and second electrodes, and having a blanket dielectric layer and a partial dielectric layer, and
source and drain regions of a transistor electrically connected with the first electrode,
wherein the blanket dielectric layer is disposed between the first and second electrodes, and the partial dielectric layer is disposed between the blanket dielectric layer and the anti-oxidation pattern.

13. The semiconductor device according to claim 12, wherein the conductive pattern is a titanium nitride (TiN) layer.

14. The semiconductor device according to claim 12, wherein the conductive pattern has one of a cylindrical or concave structure.

15. The semiconductor device according to claim 14, wherein the anti-oxidation pattern covers an inner wall of the conductive pattern.

16. The semiconductor device according to claim 15, wherein the blanket dielectric layer covers inner and outer walls of the first electrode.

17. The semiconductor device according to claim 15, wherein the anti-oxidation pattern is a binary metal electrode containing aluminum.

18. The semiconductor device according to claim 17, wherein the anti-oxidation pattern is a titanium aluminum nitride (TiAlN) layer.

19. The semiconductor device according to claim 17, wherein the partial dielectric layer is an aluminum oxide (AlO) layer.

20. The semiconductor device according to claim 12, wherein the blanket dielectric layer comprises one selected from the high-k dielectric group consisting of a hafnium oxide (HfO) layer, a zirconium oxide (ZrO) layer, an aluminum oxide (AlO) layer, a titanium oxide (TiO) layer, and a combination thereof.

21. The semiconductor device according to claim 12, further comprising:
an interlayer insulating layer disposed between the first electrode, and the source and drain regions, and
a contact plug passing through the interlayer insulating layer; and disposed between the first electrode, and the source and drain regions.

22. The semiconductor device according to claim 21, further comprising an ohmic contact layer disposed between the conductive pattern and the contact plug.

23. The semiconductor device according to claim 22, wherein the ohmic contact layer is a titanium silicide (TiSi) layer.

24. A method of fabricating a semiconductor device, comprising:
forming a first electrode having a conductive pattern and an anti-oxidation pattern contacting the conductive pattern on a substrate;
forming a capacitor dielectric layer covering the first electrode, the capacitor dielectric layer having a blanket dielectric layer covering the first electrode and a partial dielectric layer between the blanket dielectric layer and the anti-oxidation pattern; and
forming a second electrode overlapping the first electrode.

25. The method according to claim 24, wherein the conductive pattern is formed having one of a cylindrical or concave structure.

26. The method according to claim 25, wherein the anti-oxidation pattern is formed to cover an inner wall of the conductive pattern.

27. The method according to claim 26, wherein the anti-oxidation pattern is formed of a binary metal electrode containing aluminum.

28. The method according to claim 27, wherein the anti-oxidation pattern is formed of a titanium aluminum nitride (TiAlN) layer.

29. The method according to claim 27, wherein the forming of the capacitor dielectric layer comprises:
oxidizing a surface of the anti-oxidation pattern, and forming the partial dielectric layer formed of an aluminum oxide (AlO) layer, and
forming the blanket dielectric layer on the partial dielectric layer and the conductive pattern.

30. The method according to claim 29, wherein the oxidizing of the surface of the anti-oxidation pattern includes one of making oxygen (O₂) or ozone (O₃₎ flow on the surface of the anti-oxidation pattern, or a rapid thermal oxidation method.

31. The method according to claim 27, wherein the forming of the capacitor dielectric layer comprises:
forming the blanket dielectric layer on the anti-oxidation pattern and the conductive pattern; and
oxidizing the surface of the anti-oxidation pattern and forming the partial dielectric layer formed of an aluminum oxide (AlO) layer.

32. The method according to claim 31, wherein the blanket dielectric layer is formed of a material layer having a permittivity higher than or equal to that of the AlO layer.

33. The method according to claim 24, further comprising:
forming source and drain regions of a transistor electrically connected to the first electrode on the substrate;
forming an interlayer insulating layer between the source and drain regions and the first electrode, and
forming a contact plug passing through the interlayer insulating layer, and contacting the source and drain regions and the first electrode.

34. The method according to claim 33, further comprising forming an ohmic contact layer between the conductive pattern and the contact plug.
